(19) United States
(12) Patent Application Publication
(10) Pub. No.: US 2009/0008135 A1
(43) Pub. Date: Jan. 8, 2009

(54) CIRCUIT SUBSTRATE

(75) Inventor: Chih-Peng Fan, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNIMICRON TECHNOLOGY CORP., Taoyuan (TW)

(21) Appl. No.: 12/208,351

(22) Filed: Sep. 11, 2008

Related U.S. Application Data
(62) Division of application No. 11/734,257, filed on Apr. 11, 2007.

(30) Foreign Application Priority Data
Jan. 2, 2007 (TW) 96100082

(51) Int. Cl. H05K 1/03

(52) U.S. Cl. 174/255

(57) ABSTRACT

A surface treatment process for a substrate is provided. There are a plurality of first conductive patterns on a top surface of the substrate and a plurality of second conductive patterns on a bottom surface of the substrate and a plurality of inner circuits electrically connected with the first conductive patterns and the second conductive patterns. The process includes the following steps. First, a conductive layer is formed on the second conductive patterns. Next, an insulating layer is formed on the conductive layer. After the insulating layer is formed, an anti-oxidizing layer is electroplated on the first conductive patterns using the conductive layer. Next, the insulating layer and the conductive layer are removed in sequence. The surface treatment process of the present invention has the advantage of low fabrication cost and does not need a plating bar to perform the electroplating process or a photolithographic process.

### CROSS-REFERENCE TO RELATED APPLICATION

This application is a divisional of an application Ser. No. 11/734,257, filed on Apr. 11, 2007, now pending, which claims the priority benefit of Taiwan application serial no. 96100082, filed on Jan. 2, 2007. The entirety of the above-mentioned patent applications is hereby incorporated by reference herein and made a part of this specification.

### BACKGROUND OF THE INVENTION

1. Field of the Invention

The present invention relates to a substrate and a surface treatment process thereof, and more particularly to a substrate with an anti-oxidizing layer and a method of forming the anti-oxidizing layer thereof.

2. Description of Related Art

Printed circuit board (PCB) has a plurality of connection pads thereon for electrical connecting and assembling with a plurality of electronic devices and chips. A nickel/gold (Ni/Au) layer is normally formed on the surface of the connection pads to protect the connection pads from oxidation and keep a good reliability between the connection pads and the electronic devices even the chips. At present, the method of forming the nickel/gold layer includes an electroplating tie-bar process and a conductive layer process. In the conductive layer process, a nickel/gold layer is electroplated on the surface of the connection pads through the conductive layer so that there is unnecessary to pre-fabricate electroplating tie-bars.

FIGS. 1A through 1H are schematic cross-sectional views showing the steps in a conventional process for electroplating a nickel/gold layer using a conductive layer. As shown in FIG. 1A, a substrate 110 is patterned to define a desired pattern and a plurality of top connection pads 112a and a plurality of corresponding bottom connection pads 112b. The top connection pads 112a and the bottom connection pads 112b are located on a top surface 110a and a bottom surface 110b of the substrate 110 respectively. Furthermore, electrical signals are transmitted among the top connection pads 112a and bottom connection pads 112b by way of the conductive traces (not shown) that include plating through holes and/or interconnection circuit layers and conductive vias. Next, as shown in FIG. 1B, conductive layers 120a and 120b are formed on the top surface 110a and the bottom surface 110b of the substrate 110 respectively. Next, photoresist layers 130a and 130b are formed on the conductive layer 120a and 120b respectively. Hence, the conductive layers 120a, 120b and the photoresist layers 130a, 130b cover the top connection pads 112a and the bottom connection pads 112b for sequent first photolithographic process.

As shown in FIGS. 1B and 1C, patterned photoresist layers 130a′ and 130b′ are formed by removing a portion of photoresist after the photoresist layers 130a and 130b being developed. The patterned photoresist layers 130a′ and 130b′ have a plurality of openings H1 and H2 that expose a portion of the conductive layers 120a and 120b.

Next, as shown in FIG. 1D, the conductive layers 120a and 120b exposed through the openings H1 and H2 are etched to form patterned conductive layers 120a′ and 120b′ and expose the top connection pads 112a and the bottom connection pads 112b respectively. Because some residues from the patterned conductive layers 120a′ and 120b′ may be retained near the edges of the openings H1 and H2 (indicated by ‘X’ in FIG. 1D) due to the difficulties of completely etching in an etching process, a second photolithographic process is required to cover the patterned conductive layers 120a′ and 120b′. Thereafter, as shown in FIG. 1E, photoresist layers 140a and 140b are formed and then the second photolithographic process is performed. Next, the photoresist layers 140a and 140b are developed to form photoresist layers 140a′ and 140b′ in FIG. 1F. Since the diameter of both the openings P1 and P2 in the photoresist layers 140a′ and 140b′ is smaller than the diameter of the openings H1 and H2 (refer to FIG. 1D), the photoresist layers 140a′ and 140b′ can completely cover the patterned conductive layers 120a′ and 120b′. Furthermore, the top connection pads 112a and the bottom connection pads 112b are only partially exposed.

As shown in FIG. 1G, a nickel/gold layer 150 is electroplated on each the surface of the top connection pads 112a and the bottom connection pads 112b to serve as an anti-oxidation layer. Because the bottom connection pads 112b are electrically connected with the patterned conductive layer 120b′ through the circuit (not shown) on the bottom surface 110b, the nickel/gold layer 150 can be electroplated on each the surface of the bottom connection pads 112b through the patterned conductive layer 120b′.

Thereafter, the patterned photoresist layers 140a′, 140b′, 130a′ and 130b′ and the patterned conductive layers 120a′, 120b′ are sequentially removed. After that, as shown in FIG. 1H, a top solder-mask layer 160a and a bottom solder-mask layer 160b are coated on the top surface 110a and the bottom surface 110b of the circuit substrate 110 respectively. The top solder-mask layer 160a and the bottom solder-mask layer 160b partially expose the top connection pads 112a and the bottom connection pads 112b. Thus, the surface treatment process for the printed circuit board 110′ is almost completed.

However, because the foregoing electroplating process using the conductive layers includes twice photolithographic processes, the precision of alignment in the exposure could be a key problem. Hence, it is not capable for producing high-density circuit substrates. Moreover, the surface damages of the top connection pads 112a and the bottom connection pads 112b may be caused by the etch processing when the conductive layers 120a and 120b were patterned to form the conductive layers 120a′, 120b′ (as shown in FIG. 1D). Furthermore, a portion of the bottom solder-mask layer 160b partially covers the nickel/gold layer 150 (the Y area in FIG. 1H) on the bottom connection pads 112b. The bottom solder-mask layer 160b may easily peel off causing functional problems because of the poor adhesive strength between the bottom solder-mask layer 160b and the nickel/gold layer 150 is low. So does the similar condition on the top connection pads 112a (not shown).

### SUMMARY OF THE INVENTION

Accordingly, the present invention is directed to a circuit substrate, wherein the peeling of a solder-mask layer formed thereon may be prevented.

The present invention is also directed to a suitable surface treatment process for forming a conductive layer on a surface of the substrate and then electroplating an anti-oxidizing layer on the connection pads on the other surface of the substrate.

The present invention is also directed to a capable surface treatment process for electroplating an anti-oxidizing layer on the connection pads of the substrate surface without performing any photolithographic process.

To achieve these and other advantages, as embodied and broadly described herein, the invention provides a surface treatment process for a substrate. The substrate has a plurality of first conductive patterns exposed on a top surface and a plurality of second conductive patterns exposed on a bottom surface, and a plurality of inner circuits electrically connecting with the first conductive patterns and the second conductive patterns. The substrate surface treatment process includes the following steps. First, a first solder-mask layer and a second solder-mask layer are formed on the top surface and the bottom surface of the substrate respectively. Next, a conductive layer is formed on both the second conductive patterns and the second solder-mask layer. After the insulating layer is formed on the conductive layer, an anti-oxidizing layer is electroplated on the first conductive patterns using the conductive layer. Next, the insulating layer and the conductive layer are sequentially removed.

According to an embodiment of the present invention, the first and the second solder-mask layers are fabricated using an insulating material.

According to an embodiment of the present invention, the material forming the anti-oxidizing layer includes nickel, gold, nickel/gold, tin or tin/lead alloy.

According to an embodiment of the present invention, the method further includes forming a plurality of passivative layers on the second conductive patterns after removing the conductive layer.

According to an embodiment of the present invention, the material forming the passivative layers includes a high molecular weight material, tin or tin/lead alloy.

According to an embodiment of the present invention, the conductive layer is formed on the second conductive patterns by performing a physical vapor deposition (PVD) process.

According to an embodiment of the present invention, the conductive layer is formed on the second conductive patterns by performing a chemical vapor deposition (CVD) process.

According to an embodiment of the present invention, the method of removing the conductive layer includes the chemical etching process.

According to an embodiment of the present invention, the insulating layer is formed on the conductive layer by coating or film pressing.

The present invention also provides a circuit substrate comprising a substrate, an anti-oxidizing layer, a first solder-mask layer and a second solder-mask layer. There are a plurality of first conductive patterns exposed on top surface of the substrate and a plurality of second conductive patterns exposed on bottom surface of the substrate, and a plurality of inner circuits electrically connecting with the first conductive patterns and the second conductive patterns. The anti-oxidizing layer is electroplated upon the first conductive patterns according to the foregoing surface treatment process. The first solder-mask layer is disposed on the top surface of the substrate and exposes the first conductive patterns and the anti-oxidizing layer. The second solder-mask layer is disposed on the bottom surface of the substrate and exposes a part of area of the second conductive patterns.

According to an embodiment of the present invention, the circuit substrate further includes a plurality of passivative layers. The passivative layers are disposed on the second conductive patterns.

According to an embodiment of the present invention, the material forming the passivative layer includes a high molecular weight material, tin, or lead/tin alloy.

According to an embodiment of the present invention, the first conductive patterns are a plurality of connection pads.

According to an embodiment of the present invention, the second conductive patterns are a plurality of solder ball pads.

According to an embodiment of the present invention, the material forming the anti-oxidizing layer includes nickel, gold, nickel/gold or tin.

According to an embodiment of the present invention, the material forming the first conductive patterns and the second conductive patterns includes copper, aluminum or aluminum/copper alloy.

According to an embodiment of the present invention, the substrate further includes a third conductive pattern. The third conductive pattern is disposed on the top surface and covered with the first solder-mask layer.

In the present invention, the anti-oxidizing layer on the surface of the first conductive patterns is formed without performing any photolithographic process under the conductive layer on the second conductive patterns is utilized. Therefore, comparing with the conventional technique, the present invention provides the advantages of a simpler process and a lower cost.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1H are schematic cross-sectional views showing the steps in a conventional process for electroplating a nickel/gold layer using a conductive layer.

FIGS. 2A through 2G are schematic cross-sectional views showing a surface treatment process of a substrate according to one embodiment of the present invention.

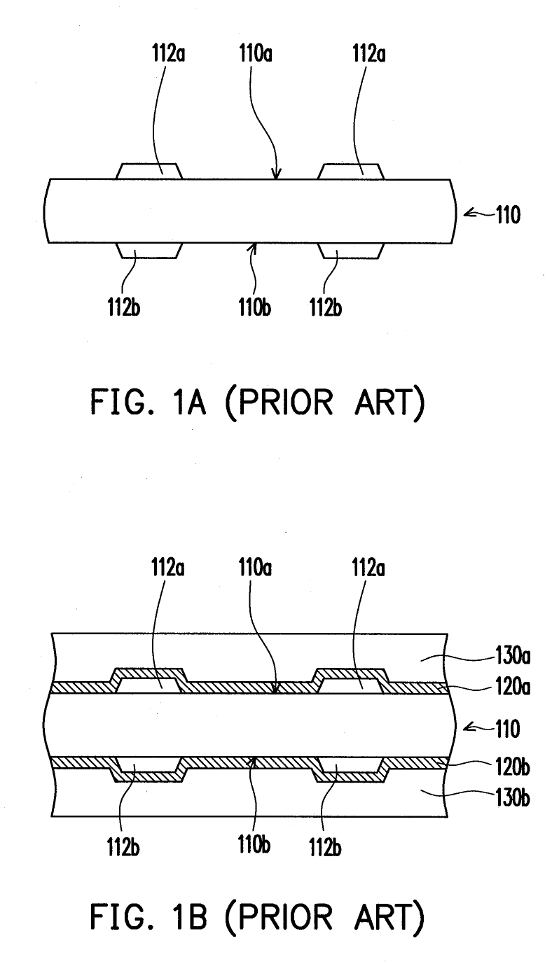

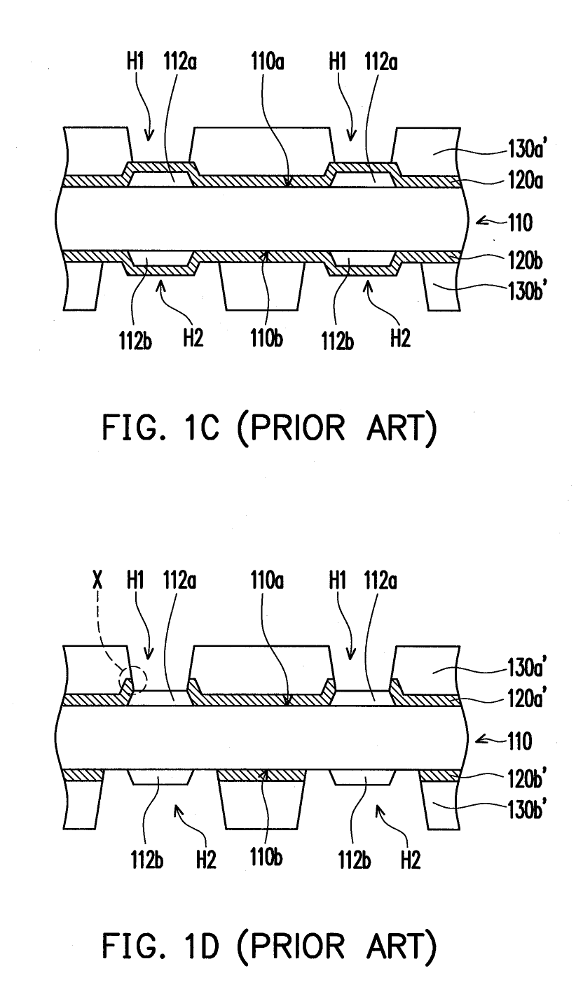

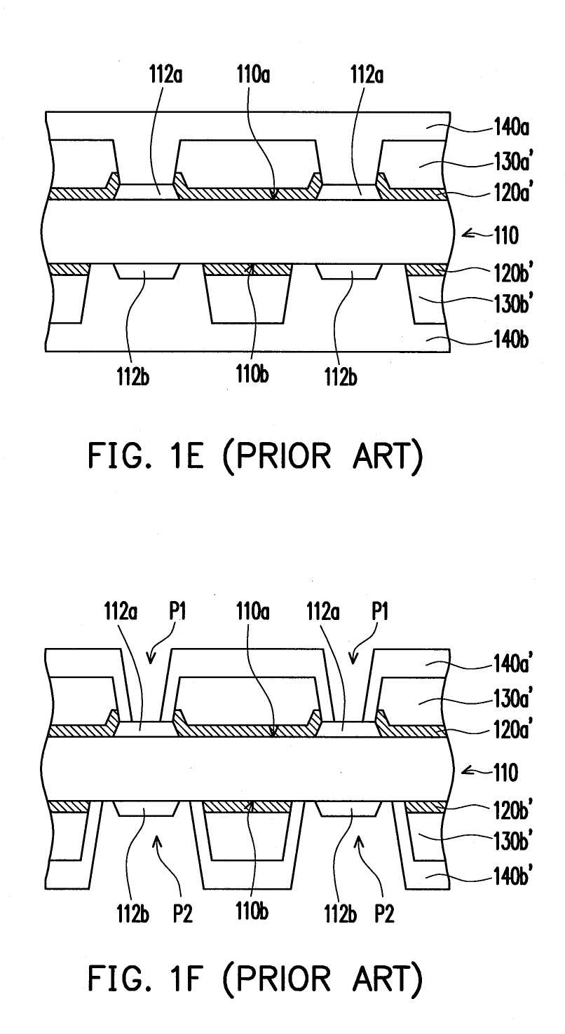

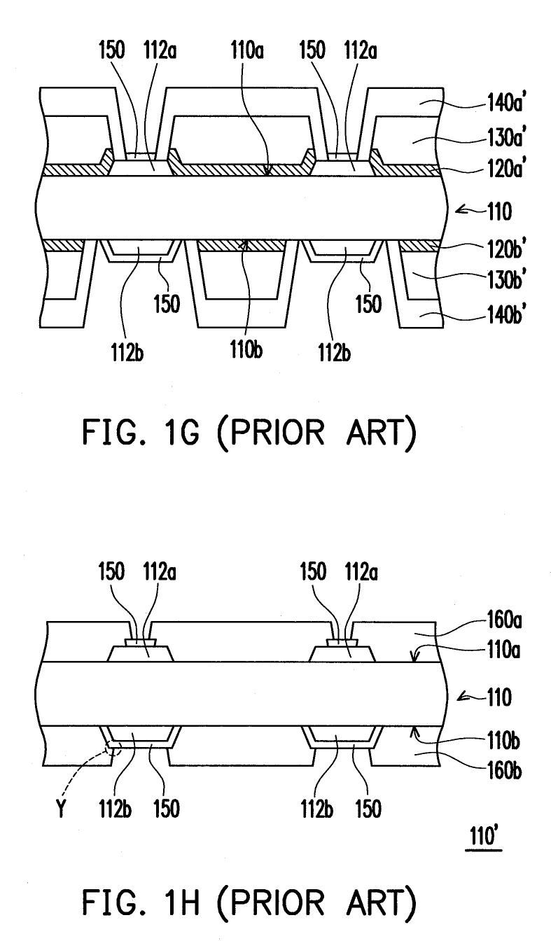

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

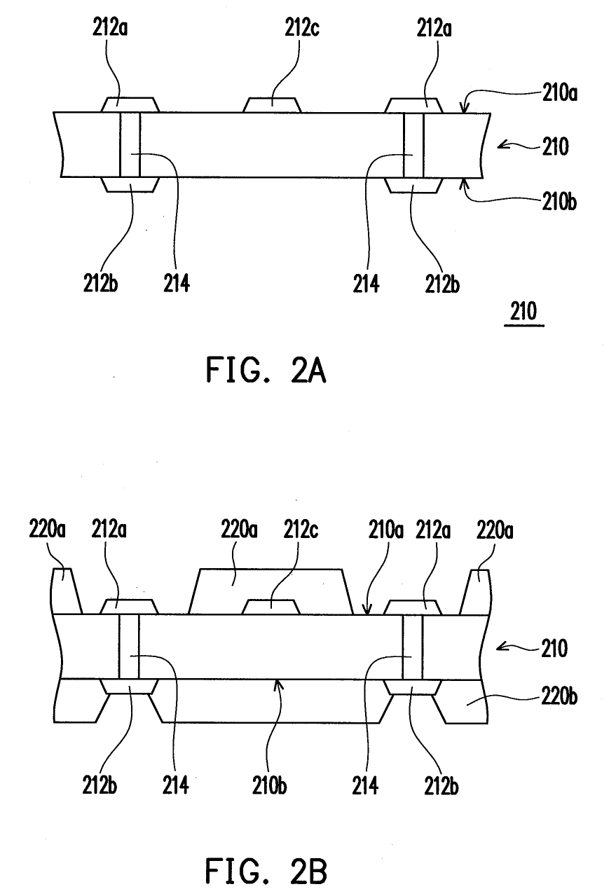

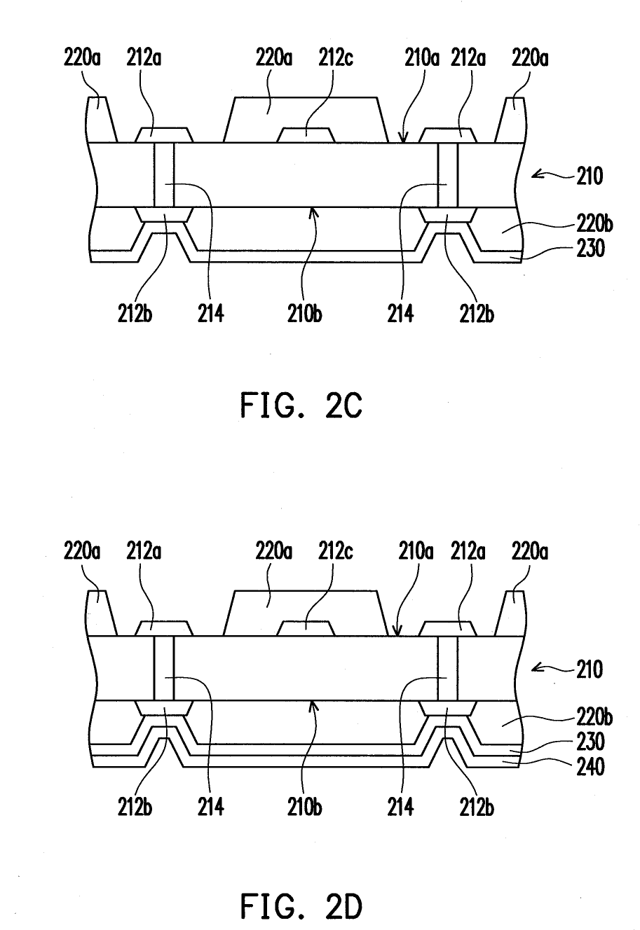

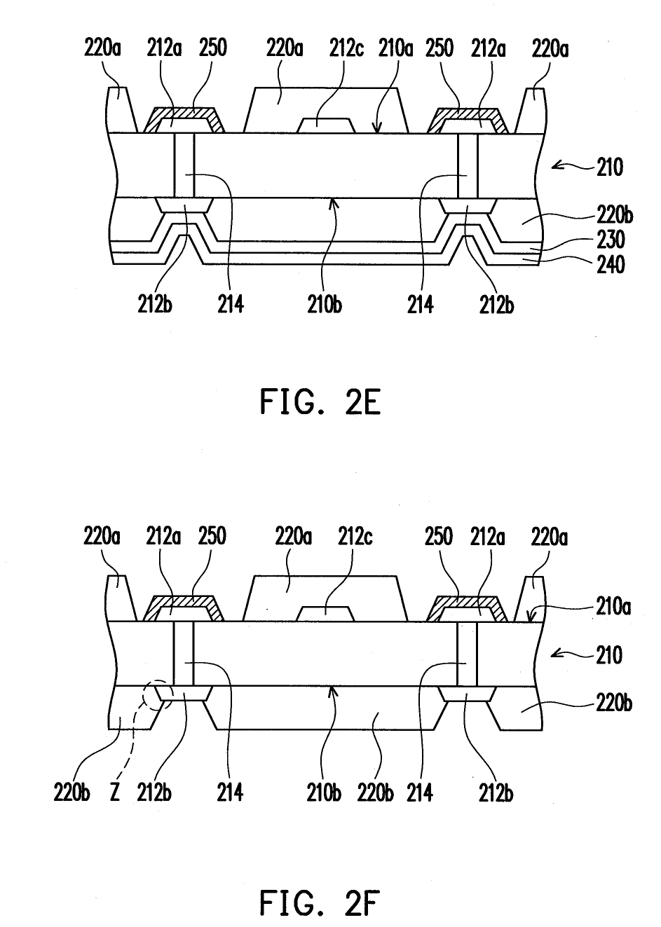

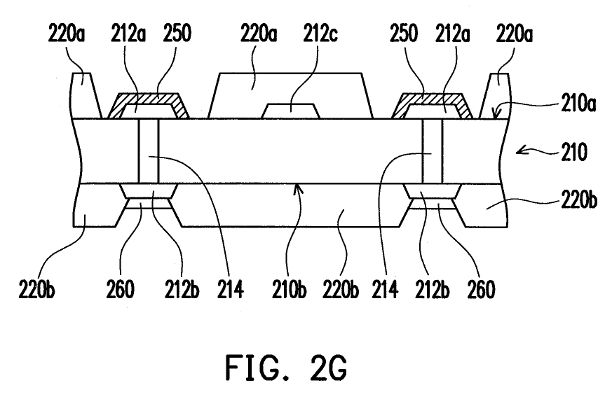

FIGS. 2A through 2G are schematic cross-sectional views showing a surface treatment process of a substrate according to one embodiment of the present invention. First, as shown in FIG. 2A, there are a plurality of first conductive patterns 212a exposed on a top surface 210a of the substrate 210, and a plurality of second conductive patterns exposed on a bottom surface 210b of the substrate 210, and a plurality of inner circuits 214 electrically connected among the first conductive patterns 212a and the second conductive patterns 212b. The substrate 210 may be comprised of, for example but not limited to, a printed circuit board (PCB), a flexible circuit board, a double-sided circuit board, a multi-layer circuit board and the like.

The first conductive patterns 212a serve bonding pads for assembling and electrically connecting with a plurality of electronic devices or chips, for example. The second conductive patterns 212b serve solder ball pads, for example. The material of the first conductive patterns 212a and the second conductive patterns 212b includes copper, aluminum, aluminum/copper alloy or other suitable conductive materials, for example. The types of inner circuits 214 can be different according to the kinds of substrate 210 (for example, double-side circuit board or multi-layer circuit board). Therefore, the plated through hole (PTH) and the conductive plug in FIG. 2A serves as examples of the inner circuits 214 and should not be used to limit the scope of the present invention.

Furthermore, the substrate 210 may include a third conductive pattern 212c. The third conductive pattern 212c may be exposed on the top surface 210a and can be a conductive trace. In addition, the third conductive pattern 212c and the first conductive patterns 212a may be composed of a same layer.

As shown in FIG. 2B, the surface treatment process of the substrate in the present invention includes the following steps. First, a first solder-mask layer 220a and a second solder-mask layer 220b are formed on the top surface 210a and the bottom surface 210b respectively. The first solder-mask layer 220a exposes the first conductive patterns 212a on the top surface 210a but covers the third conductive pattern 212c. The second solder-mask layer 220b at least covers a part of the second conductive patterns 212b on the bottom surface 210b. The material of the first solder-mask layer 220a and the second solder-mask layer 220b includes an insulating material, for example, a polymer with high molecular weight.

As shown in FIG. 2C, a conductive layer 230 is formed on the second conductive patterns 212b and the second solder-mask layer 220b. The conductive layer 230 can be formed, for example, by sputtering, evaporation or other suitable physical vapor deposition method, or by electroless plating, chemical vapor deposition (CVD) or other suitable chemical deposition method. Furthermore, the conductive layer 230 may be formed using the same material as the first conductive patterns 212a and the second conductive patterns 212b.

As shown in FIG. 2D, an insulating layer 240 is formed on the conductive layer 230 by using a coating or a film pressing method. The insulating layer 240 is fabricated using an insulating material selected from photoresist, solderability preservatives, polymer with high molecular weight or other suitable insulating material.

As shown in FIG. 2E, an anti-oxidizing layer 250 is electroplated on the first conductive patterns 212a using the conductive layer 230 after forming the insulating layer 240. In addition, the material of the anti-oxidizing layer 250 may include nickel, gold, nickel/gold, tin, tin/lead alloy or other suitable anti-oxidizing conductive material.

After the anti-oxidizing layer 250 is formed, the insulating layer 240 and the conductive layer 230 are removed in sequence. The method of removing the conductive layer 230 includes chemical etching process. As shown in FIG. 2F, after removing the insulating layer 240 and the conductive layer 230 (refer to FIG. 2E), the second conductive patterns 212b are at least partially exposed through the second solder-mask layer 220b on the bottom surface 210b of the substrate 210. The first solder-mask layer 220a exposes the first conductive patterns 212a and the anti-oxidizing layer 250 on the top surface 210a of the substrate 210.

The second solder-mask layer 220b directly covers part of the second conductive patterns 212b (the area Z in FIG. 2F), that is, part of the second solder-mask layer 220b is directly adhered to the second conductive patterns 212b. The second solder-mask layer 220b may be fabricated using a polymer with high molecular weight and the second conductive patterns 212b may be fabricated using copper. Since the adhesion between high molecular weight polymer and copper is relatively large, the peeled possibility of the second solder-mask layer 220b from the second conductive patterns 212b compared with the conventional technique is reduced.

As shown in FIG. 2G, a plurality of passivative layers 260 may also be formed on the second conductive patterns 212b in the present embodiment after removing the conductive layer 230. The passivative layers 260 can protect the second conductive patterns 212b from damage or oxidation. The passivative layer 260 may include polymer with high molecular weight (for example, solderability preservatives), tin or tin/lead alloy, and the method of forming the passivative layers 260 may include immersion, coating or printing.

In summary, the characteristics of the present invention is to form the first and the second solder-mask layer first, then to form the conductive layer on the second conductive patterns and the second solder-mask layer on the bottom surface. Hence, the anti-oxidizing layer can be electroplated on the surface of the first conductive patterns without the performing a photolithographic process. Thus, the present invention uses a simpler process and has the advantage of a lower fabrication cost.

Furthermore, because the anti-oxidizing layer has already formed on the surface of the first connection pads prior to etching the conductive layer, the surface of the first connection pads will not be damaged by the etching process.

In addition, the second solder-mask layer is directly adhered to the second conductive patterns on the bottom surface of the substrate so that the adhesion between the second solder-mask layer and the second conductive patterns is greater compared with the conventional technique. Consequently, the peeled possibility of the second solder-mask layer from the second conductive patterns may be effectively reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit substrate, comprising:
a substrate, having a plurality of first conductive patterns on a top surface of the substrate, a plurality of second conductive patterns on a bottom surface of the substrate and a plurality of inner circuits electrically connected with the first conductive patterns and the second conductive patterns;
a first solder-mask layer, disposing on the top surface of the substrate and exposing the first conductive patterns;
an anti-oxidizing layer, busless electroplating on the first conductive patterns; and
a second solder-mask layer, disposing on the bottom surface of the substrate and exposing at least a part of area of the second conductive patterns.

2. The circuit substrate of claim 1, further comprising a plurality of passivative layers disposed on the second conductive patterns.

3. The circuit substrate of claim 2, wherein the passivative layer comprises polymer with high molecular weight, tin, or tin/lead alloy.

4. The circuit substrate of claim 1, wherein the first conductive patterns comprise a plurality of connection pads.

5. The circuit substrate of claim 1, wherein the second conductive patterns comprise a plurality of solder ball pads.

6. The circuit substrate of claim 1, wherein the anti-oxidizing layer comprises nickel, gold, nickel/gold or tin.

7. The circuit substrate of claim 1, wherein the first conductive patterns and the second conductive patterns comprise copper, aluminum or aluminum/copper alloy.

8. The circuit substrate of claim 1, wherein the substrate further comprises a third conductive pattern disposed on the top surface such that the first solder-mask layer covers the third conductive pattern.

9. The circuit substrate of claim 8, wherein the third conductive pattern comprises a conductive trace.

10. The circuit substrate of claim 1, further comprising:
another anti-oxidizing layer, busless electroplating on the part of area of the second conductive patterns, wherein the side of the anti-oxidizing layer substantially connects with the side of the second solder-mask side by side.

11. The circuit substrate of claim 10, wherein the anti-oxidizing layer on the part of area of the second conductive patterns comprises nickel, gold, nickel/gold or tin.
